(19) United States
(12) Patent Application Publication
(10) Pub. No.: US 2013/0207715 A1
(43) Pub. Date: Aug. 15, 2013

(54) Method, Apparatus, Computer Program, Cable and System

(71) Applicants: Antti SALO, Lohja (FI); Jarkko SAUNAMÄKI, Vantaa (FI); Tapani JOKINEN, Espoo (FI); Teemu AHMANIEMI, Helsinki (FI); Juha KOSONEN, Porvoo (FI)

(72) Inventors: Antti SALO, Lohja (FI); Jarkko SAUNAMÄKI, Vantaa (FI); Tapani JOKINEN, Espoo (FI); Teemu AHMANIEMI, Helsinki (FI); Juha KOSONEN, Porvoo (FI)

(73) Assignee: Nokia Corporation

(21) Appl. No.: 13/371,748

(22) Filed: Feb. 13, 2012

(51) Int. Cl. H03K 17/96

(52) U.S. Cl. 327/517

(57) ABSTRACT

A method, apparatus, computer program, cable and system are provided for: receiving a signal relating to a detection of a touch on a cable; determining a location on the cable of the touch; and controlling an apparatus, which is in communication with the cable, based on the detected touch and the determined location of the touch.

### FIELD OF THE INVENTION

Embodiments of the present invention relate to a method, apparatus, computer program, cable and system. In particular, though without prejudice to the foregoing, embodiments relate to a method apparatus, computer program, cable and system for remotely controlling an apparatus via user interaction with a cable which is in communication with the apparatus.

### BACKGROUND TO THE INVENTION

It is known to provide earphones or headsets for electronic devices such as media players, mobile phones and tablets with a unit that comprises one or more keys/switches to enable remote control of the electronic device, for example: play/pause, volume up/down or skip a track. However, the unit and its keys have a small form factor which can lead to difficulty in locating and operating a key and performing a desired control operation.

The listing or discussion of a prior-published document or any background in this specification should not necessarily be taken as an acknowledgement that the document or background is part of the state of the art or is common general knowledge. One or more aspects/embodiments of the present disclosure may or may not address one or more of the background issues.

### BRIEF DESCRIPTION OF VARIOUS EMBODIMENTS OF THE INVENTION

According to various, but not necessarily all, embodiments of the invention there is provided a method comprising causing, at least in part, actions that result in:
receiving a signal relating to a detection of a touch on a cable;
determining a location on the cable of the touch; and
controlling an apparatus, which is in communication with the cable, based on the detected touch and the determined location of the touch.

According to various, but not necessarily all, embodiments of the invention there is provided an apparatus comprising:

at least one processor; and
at least one memory storing computer program instructions configured, working with the at least one processor, to cause the apparatus to perform the method set out above.

According to various, but not necessarily all, embodiments of the invention there is provided an apparatus comprising means for performing the method set out above.

According to various, but not necessarily all, embodiments of the invention there is provided a non-transitory computer readable medium storing computer program instructions that, when performed by at least one processor, causes the method as set out above.

According to various, but not necessarily all, embodiments of the invention there is provided a cable comprising at least one sensor configured to:
detect a touch of a cable; and
generate a signal for controlling an apparatus, which is in communication with the cable, wherein the signal is representative of the detected touch and a location of the touch.

According to various, but not necessarily all, embodiments of the invention there is provided a system comprising the apparatus as set out above and the cable as set out above.

### BRIEF DESCRIPTION OF THE DRAWINGS

For a better understanding of various examples of embodiments of the present invention reference will now be made by way of example only to the accompanying drawings in which:

FIG. 1 schematically illustrates a flow chart illustrating a method of an embodiment of the invention;

FIG. 2 schematically illustrates a system according to an embodiment of the invention;

FIGS. 3A, 3B, 4A and 4B schematically illustrate user interactions with a cable;

FIG. 5 schematically illustrates a flow chart illustrating a further method of an embodiment of the invention;

FIG. 6 schematically illustrates a flow chart illustrating a further method of an embodiment of the invention;

FIG. 7 schematically illustrates a cable according to an embodiment of the invention; and

FIG. 8 schematically illustrates a system according to an embodiment of the invention.

### DETAILED DESCRIPTION OF VARIOUS EMBODIMENTS OF THE INVENTION

The Figures, and in particular FIG. 2, schematically illustrate a system in which an apparatus 201 is connected to a device 203 via a flexible cable 202. The cable comprises a sensor 205 which generates a signal relating to a detection of a touch on the cable. The touch can be detected along the length of the cable. The signal is received by the apparatus. A location of the touch along a length of the cable is determined. The apparatus is then controlled based on both the detected touch and the determined location of the touch.

Additionally, further sensors for detecting other user interactions with the cable, i.e. a bending, a stretching or a contracting of the cable may be provided. Furthermore, a magnitude, direction, timing and location of such user interactions may be determined. Based on these values, a manipulation of the cable can be determined (for example: a looping of a particular section of the cable, a flicking of an end portion of the cable or a twanging of an opposite end of the cable) based on which the apparatus can be controlled.

Advantageously, since embodiments of the invention are able to detect and determine a plurality of aspects of a user's interaction with the cable, a large variety of interactions/manipulations can be determined and uniquely identified thereby enabling a large variety of different apparatus controls to be effected based on the user's interaction with the cable.

### DESCRIPTION

Examples of embodiments of the invention will now be described with reference to the Figures.

In the Figures, only the functional components that are necessary for describing the operation of embodiments of the invention are described. Similar reference numerals are used in the Figures to designate similar features. For clarity, not all reference numerals are necessarily displayed in all of the Figures.

Although embodiments of the apparatus have been described below in terms of comprising various components, it should be understood that the components may be embodied as or otherwise controlled by a corresponding controller, processing element or processor. In this regard, each of the components described may be any device, means or circuitry embodied in hardware, software or a combination of hardware and software that is configured to perform the corresponding functions of the respective components as described in greater detail below. Implementation of the controller can be in hardware alone (a circuit, a processor . . . ), have certain aspects in software including firmware alone or can be a combination of hardware and software (including firmware).

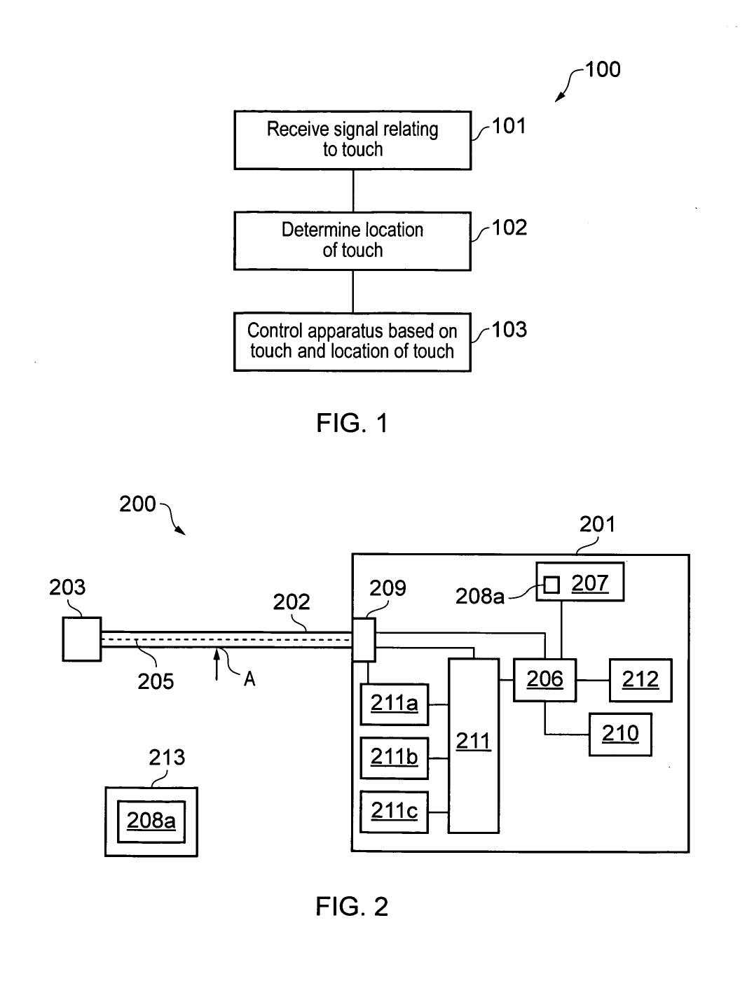

FIG. 1 schematically illustrates a flow chart of a method 100 of an embodiment of the invention.

In block 101, a signal relating to a detection of a touch 204 on a cable 202 is received. The signal is generated by a sensor 205 embedded within or located on the surface of the cable. The signal is conveyed to and received by the apparatus via the cable

The sensor could comprise a thin resistive sensor that produces an output based on a touch occurring anywhere along the length of the thin sensor strip. Alternatively, the sensor may comprise a printed conductive ink press sensor, or detect a change of capacitance upon a user's touch. An array of such sensors could be layered on an external surface of the cable. Values could be read from reading the values from each sensor (http://www.sensorprod.com/freeform.php).

The cable is in electrical or logical connection with/coupled to an apparatus 201. The cable is also in electrical or logical connection with /coupled to a device 203, thereby rendering the device in operable communication with the apparatus. For example, in one particular embodiment, the apparatus 201 is a portable electronic device, the device 203 is a set of earphone speakers and the cable comprises wires that connect the earphone speakers to the portable electronic device.

In block 102, a location (A) at a point along the length of the cable where the touch occurred is determined. This determination can be made based on location information included in the signal itself, or can be made based on determining which particular sensor detected the touch (for example in view of which signal line the signal is received from) and foreknowledge of a location of the particular sensor on the cable.

In block 103, the apparatus is controlled based on the detected touch and the determined location of the touch. For example, a control signal could be generated by the apparatus in response to the detected touch and determined location which is used to control an operation or function of the apparatus or an operation or function of a software application running on the apparatus so as to affect an audio or visual output from the apparatus. Also, there the apparatus controls the device, the controlling of the apparatus can cause a control on the device.

Advantageously, in certain embodiments of the invention a single user interaction, namely a touch of the cable can give rise to a plurality of different controls of the apparatus depending on where the user touches the cable. This increases the efficiency of user input and decreases the number of user interactions required to bring about a particular control operation. This also increases the ease of use of user input as the user input area can correspond to an entire or substantial portion of the cable's length.

For example, in one non-limiting example, the apparatus is a media player and the control relates to, not least, controlling the playback selection of media. For instance, detecting a touch at a location which is at one end of the cable could effect selection of a first track in an album whilst detection of a touch at a location which is at an opposite end of the cable could effect selection of a last track in an album. Therefore, not only can the detection of a touch bring about the selection of a track, but also the additional variable of the location of the touch can determine which track is selected. In another non-limiting example, the apparatus is a music synthesiser and the control relates to, not least, generating a note of a particular pitch/frequency. For instance, detecting a touch at a location which is at one end of the cable could generate a low pitch note whilst detection of a touch at a location which is at an opposite end of the cable could generate a high pitch note. Therefore, not only can the detection of a touch bring about the generation of a note, but also the additional variable of the location of the touch can determine a pitch of the note.

In certain embodiments of the invention the control is based on a binary input (i.e. detection/non-detection of a touch) in combination with a continuously variable input (i.e. location of the touch along a length of a sensor and/or section of the cable). This provides a large number of possible uniquely identifiable inputs based on a single touch of the cable that can be mapped to unique control operations of the apparatus. Accordingly, a single user interaction with the cable, namely a touch, can be used to effect a different controls of the apparatus depending on where the touch occurs.

FIG. 2 schematically illustrates a block diagram of a system 200 according to an embodiment of the invention in which the apparatus 201 is connected to the device 203 via the cable 202.

The cable comprises one or more sensors 205 which can detect a user's touch (indicated by the arrow at location A) at a position along the cable. A signal from the sensor relating to a detection of the touch is sent to the apparatus.

The apparatus comprises a port 209 which mechanically couples and electrically connects the cable to the apparatus. Electrical signals can be sent between the cable and the apparatus. Also, electrical signals, for example audio information, can be sent between the device and the apparatus via the cable.

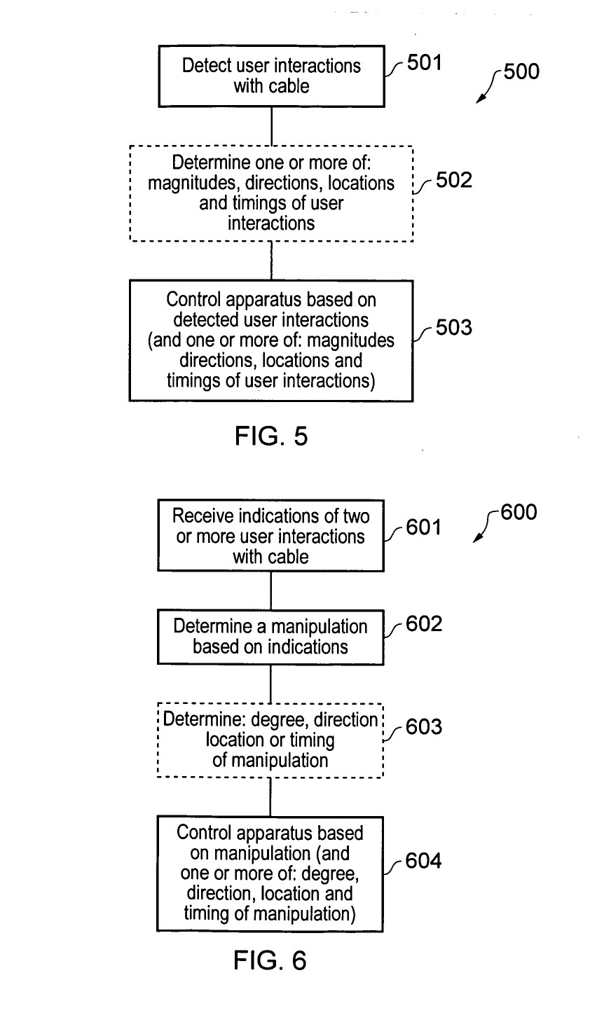

The apparatus comprises means for performing the method of the flowchart of FIG. 1 and the methods of FIGS. 5 and 6. The means may comprise a controller such as at least one processor 206; at least one memory 207 including computer program code 208a, the at least one memory and the computer program code configured to, with the at least one processor, cause the apparatus at least to perform the method of any of FIGS. 1, 5 and 6.

The processor 206 is configured to read from and write to the memory 207. The processor may also comprise an output interface 211 via which data and/or commands are output by the processor and an input interface 212 via which data and/or commands are input to the processor.

The memory 207 stores the computer program 208a comprising computer program instructions that control the operation of the apparatus 201 when loaded into the processor 206. The computer program instructions 208a provide the logic and routines that enables the apparatus to perform the methods illustrated in FIGS. 1, 5 and 6. The processor by reading the memory is able to load and perform the computer program. Although the memory 207 is illustrated as a single component it may be implemented as one or more separate components some or all of which may be integrated/removable and/or may provide permanent/semi-permanent/dynamic/cached storage.

The computer program may arrive at the apparatus 201 via any suitable delivery mechanism. The delivery mechanism may be, for example, a non-transitory computer-readable storage medium 213, a computer program product, a memory device, a record medium such as a compact disc read-only memory or digital versatile disc, an article of manufacture that tangibly embodies the computer program 208a. The delivery mechanism may be a signal configured to reliably transfer the computer program. The apparatus 201 may receive the computer program 208a as a computer data signal.

In one embodiment, the apparatus 201 is embodied on a hand held portable electronic device, such as a mobile telephone or personal digital assistant, that may additionally provide one or more audio/text/video communication functions (e.g. tele-communication, video-communication, and/or text transmission (Short Message Service (SMS)/Multimedia Message Service (MMS)/emailing) functions), interactive/non-interactive viewing functions (e.g. web-browsing, navigation, TV/program viewing functions), music recording/playing functions (e.g. Moving Picture Experts Group-1 Audio Layer 3 (MP3) or other format and/or (frequency modulation/amplitude modulation) radio broadcast recording/playing), downloading/sending of data functions, image capture function (e.g. using a (e.g. in-built) digital camera), and gaming functions.

The output interfaces 211 may comprise one or more of: an audio output mechanism 211a (e.g. speaker), visual output mechanism 211b (e.g. display) and haptic output mechanism 211c (e.g. vibrator). One or more of the output elements may be in communication with the cable 202 and the device 203. For example, where the device 203 and cable 202 comprise a headset, the audio output mechanism of the apparatus may be connected to the headset so as to output audio via a speaker of the headset.

A location (A) of the touch along a length of the cable is determined by the processor. Based on the detected touch and the determined location of the touch, a control signal is generated which is used to control the apparatus, for example control one of the audio, visual or haptic output mechanisms.

Furthermore, a determination may be made of properties of the touch such as at least one of: a magnitude of the touch, a direction of the touch, and a time of the detection of the touch. The sensor signal could itself provide vector information relating to a magnitude and direction of the detected touch. The magnitude of the touch may correspond to a pressure/force of the user's touch and/or an extent of the size or area of the touch. A Tactilus® Nano-Polymer Core sensor could be integrated to the cable to measure the pressure distribution along the cable. The direction of the touch could relate to a direction of the force/pressure applied and could be determined from information provided by the sensor itself or based on knowledge of an orientation of the location of the sensor on the cable. For example, if an elongate planer sensor were located and orientated such that its sensing plane were parallel to a side surface of a cable with a rectangular cross section, a touch signal from the sensor would indicate a touch incident in a direction perpendicular to the plane of the sensor. The time at which the touch event occurred can be determined by a clock/timer 210 in the apparatus. The time of the detection of a touch could also correspond to the duration of the touch event, so as to enable a distinction between a quick touch and a prolonged touch. The apparatus can be further controlled based on at least one of: the magnitude, the direction and the time of the touch.

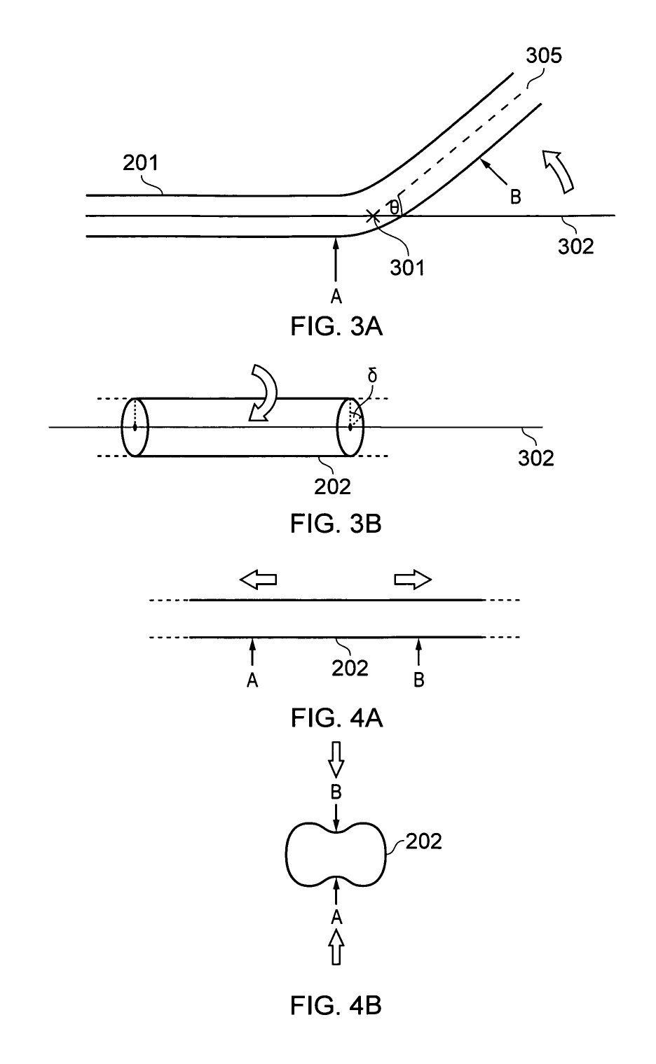

In addition to detecting a user interaction of the cable which does not necessarily result in a physical deformation of the cable, such as a user's touch of the cable, the cable may be provided with one or more sensors which detect other user interactions with the cable which do result in a physical deformation of the cable, such as: bending (FIGS. 3A and 3B) stretching (FIG. 4A) and contracting (FIG. 4B) of the cable.

FIG. 3A shows a section of cable which comprises a sensor 305 that detects a bend in the cable. The sensor may comprise a thin resistive sensor that produces an output based on the degree that the sensor is bent. A signal relating to a detection of a bend in the cable can be used to control the apparatus. A user touching/holding the cable at locations A and B provides a bending moment which bends the flexible cable. FIG. 3A shows a longitudinal bend, i.e. a bending of the cable about an axis 301 orthogonal to a longitudinal/lengthwise axis 302 of the cable by an angle θ. The bend can be detected and measured by the embedded sensor 305. Alternatively or additionally one or more touch sensors could be used to determine touch locations A and B as well as determined amounts of pressure of the touches and directions of touches which could then be used to determine the presence of a b end as well as an amount and location of the bend.

FIG. 3B shows a torsional bend, e.g. a bending of the cable about an axis parallel to and in line with the longitudinal/lengthwise axis 302 of the cable, so that one end of the cable is twisted by an angle δ about its axis with respect the other end. This type of bend can be detected and measured by an embedded sensor (not shown).

The apparatus is also configured to determine properties of the bend such as: a magnitude of the bend, a direction of the bend; a location of the bend and a time of the detection of the bend. The magnitude of the bend may correspond to an amount or angular degree of bending, e.g. θ or δ. This could be determined by a sensor configured to provide a signal having a characteristic which is proportional to the severity of the bend. The direction of the bend may correspond to a bend about a particular axis, e.g. x, y and z axes or a bend clockwise or anticlockwise.

FIG. 4A shows a stretch of the cable which can be detected and measured by a sensor (not shown) embedded within the cable itself. The figure shows a lengthwise stretch, i.e. a stretch parallel to the longitudinal/lengthwise axis, but the stretch could be perpendicular to this axis and in any dimension of the cable, e.g. a stretch of the cable's height or width/cross sectional dimensions. The figure shows two grasping points A and B which the user forces apart causing an extension of the flexible cable. FIG. 4B provides a cross sectional view of the cable showing a squeezing or contraction of the cable which can be detected and measured by a sensor (not shown). Here the figure shows height-wise contraction, but the contraction could be in any dimension of the cable, e.g. its width or length.

A signal from a sensor may provide, or the processor may determine properties such as: a magnitude; direction, location and time of each of a bend, a stretch or a contraction of the cable. The apparatus can then be controlled based on such detections and measurements.

FIG. 5 schematically illustrates a flow chart illustrating a method 500 of an embodiment of the invention. The flowchart represents one possible scenario among of hers, not all the steps are essential.

In block 501 detections of one or more user interactions with the cable, namely one or more: touches, locations of touches, bends, stretches and contraction are made. Optionally, in block 502, determination of corresponding: magnitudes, directions, and timings could also be made. Detection of multiple timing of user interactions enables a determination of speed of a user interaction. In block 503, the apparatus is controlled based on combinations of each of touches, bends, stretches and contraction (and also optionally the magnitude, direction and timings of such user interactions with the cable).

By enabling the apparatus to be controlled based on combinations of user interactions, this further increases the range of different uniquely identifiable user interactions that can be performed to effect different controlling operations of the apparatus. For example, 2 separate touches at the same location in quick succession can effect a different control operation to 2 separate touches at the same location but with a delay between the touches. Likewise, a series of sequential touch detections at locations whose distance from an end of the cable increases or decreases might correspond to user brushing/stroking/swiping/sweeping along the cable. A series of bends detected at nearby location might correspond to a user making a loop out of the cable.

FIG. 6 schematically illustrates a flow chart illustrating a method 600 of an embodiment of the invention wherein different user interactions with the cable are combined to determine a manipulation. Here, a user manipulation refers to a combination of touches, bends, stretches and contractions. The manipulation may comprise two or more different user interactions which relate to a gesture performed on the cable by a user, such as looping, twisting, flicking, twanging the cable or forming the cable into certain shapes. For example, a determination that a user had bent the cable round on itself, i.e. to make a loop manipulation, could be made based on receiving signals indicating simultaneously two touches where the user is holding on to the cable and a bending of a sufficient magnitude at a location between the touching locations. The degree and direction of the manipulation could likewise be determined, such as the size of the loop and whether or not it had been looped in a clockwise or anticlockwise direction. Likewise, a half or full twists or twirls of the cable could be similarly determined. A flicking manipulation could be determined based on a quick touch of a large magnitude followed by a detection of a bend. A twanging manipulation could be determined based on a touch of a large magnitude followed by a detection of an oscillating bend, i.e. bend which alters its direction.

Also movements of one section of the cable with respect to another to manipulate the cable to particular shapes could be determined based on detected touch, bend, stretch and contraction information, with the control of the apparatus being responsive to the determined manipulation.

In block 601 indications of two or more user interactions with the cable (i.e. two or more of: touches, bends, stretches and contractions) are received. In block 602 a determination of a manipulation is made based on the received indications. Optionally, a determination of one or more of: a degree, a direction, a location and a timing of the manipulation can be made. In block 604, the apparatus is controlled based on the determined manipulation (and also optionally also on the degree, direction, location or timing of the manipulation).

Determining a manipulation (i.e. combinations of individual user interactions with the cable, namely: touches, bends, stretches and contractions) as well as the degree, direction, location and timing of the manipulation (such as its speed of execution) provide further user interactions that can be performed on the cable and uniquely identified thereby increasing the corresponding control signals that the manipulations can be mapped to.

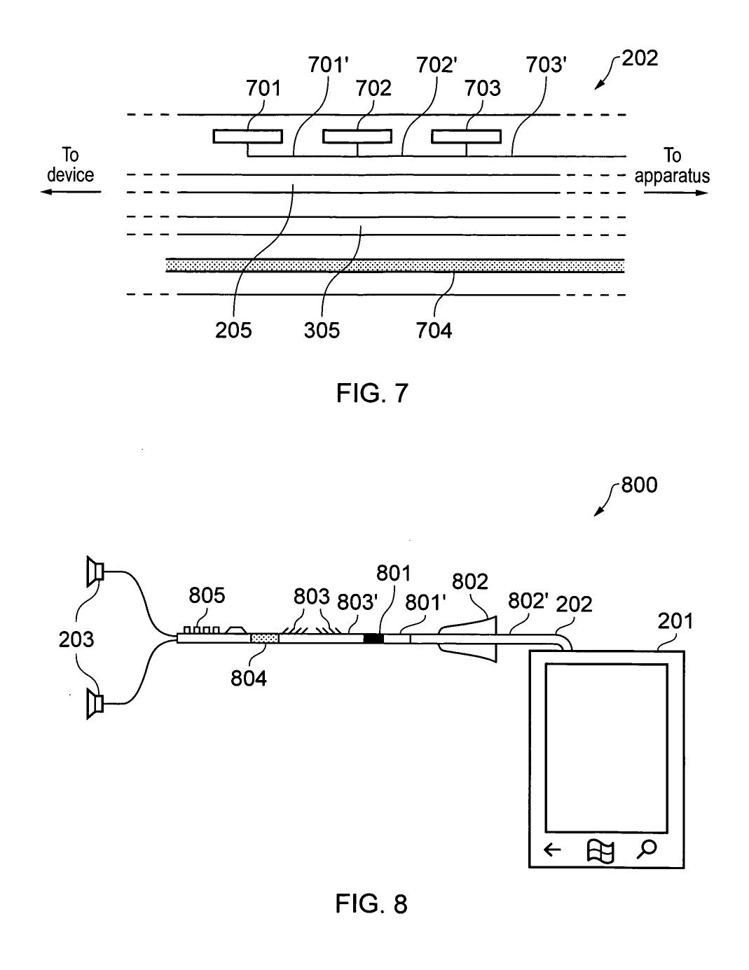

FIG. 7 schematically illustrates a cable 201 according to an embodiment of the invention, wherein the cable is provided with internal feedback elements 701, 702, 703, though the elements could be provided on an outer surface of the cable. The feedback elements which are configured to provide feedback to a user, such as visual feedback via illumination mechanism 701 or haptic feedback via vibrating mechanism 702, heating element 703, electrotactile or electrostatic tactile mechanism, in response to a user interaction with the cable, i.e. a touch, bend, stretch or contraction of the cable. The feedback elements may be arranged in an array or matrix to extend across at least a portion of the cable or may be provided on certain sides of the cable. The feedback elements may be controlled responsive to signals from the sensor or could be separately controlled by the apparatus. Signal lines 701′, 702′ and 703′ are provided from the feedback elements to the apparatus. Alternatively, the feedback elements may be directly coupled to one or more of the sensors, such as touch sensor 205, bend sensor 305, stretch sensor (not shown) and contraction sensor (not shown).

The sensors 205 305 can be arranged in an array or matrix within or on the surface of the cable. Each sensor can be provided with signal lines (not shown) via which sensor signals can be sent to the apparatus. Also, one or more signal lines 704 may be provided for convening signals between the apparatus and the device via the cable.

Alternatively or additionally to providing feedback of user interaction via the cable, feedback may be provided via the apparatus or the device, e.g. a visual output from a display of the apparatus, an audio output from an on board speaker of the apparatus (or speaker of device 203), or haptic output from a vibrator of the apparatus.

In certain embodiments of the invention, there no device 203 is present, i.e. the cable need not necessarily be coupled to the device but could instead just be coupled to the apparatus.

FIG. 8 schematically illustrates a block diagram of a system 800 according to an embodiment of the invention. Here the cable 202 is connected to speakers 203 such that the cable and speakers for a headset or earphones for the connected apparatus 201.

The cable comprises indicators 801-803 that are detectable by a user which can be used to indicate to the user sensing portions of the cable, i.e. portions of the cable where there are sensors. Therefore such indicators indicate to a user sections of the cable where a user interaction (touch, bend, stretch or contraction) could be performed.

The user identifiable indications on the cable may comprise:
a visual appearance of a sensing portion 801 differing from a visual appearance of other portions of the cable 801′ (e.g. differing colours, pattern or aesthetic features for portions 801 and 801′);
a cross-sectional dimension of a sensing portion 802 differing to a cross sectional area of other portions of the cable 802′ (e.g. differing cross sectional size and shapes for portions 802 and 802′);
a surface texture of a sensing portion 803 differing to a texture of other portions of the cable 803′ (e.g. differing haptic features such as topology, undulations 805, surface texture 803, friction, internal composition of portions 804 compared to other portions 803′). The internal composition could and its flexibility could be modified in sensing sections of the cable (i.e. segments of the cable where there are embedded sensors) for example by using compressive gel, foam or powder between a cable's core and its outer surface.

The cable of FIG. 8 is shown as being flat/substantially straight, but it is to be appreciated that the cable need to be rigid along its entire length and can be flexible. The cable could be of any suitable shape, thickness and cross section.

User interactions of the cable can be detected and measured by sensors based on one or several of the following sensing methods:
Change of resistance or conductivity by cable embedded:
   Strain gauges
   Piezo-resistive sensing (e.g. with silicon nano-wires)
   Piezoresitive inks, gels, foams, elastomers (e.g. http://www.merlinsystemscorp.co.uk/index.php/merlin-robotics-2 mm-stretch-sensor-30 cm.html wherein stretching changes the resistance of the elastomer)
   Changing a contact point and thus a length of a circuit by a planar, coaxial or intertwined structure
Piezoelectrics
   Piezoelectric foils made e.g. from PVDF (see http://www.murata.com/new/news_release/2011/0921/in dex.html)
   Piezoelectric wires like made e.g. from PZT Piezoelectric cable (http://www.meas-spec.com/product/t_product.aspx?id=2476). Here the cable is designed as a coax cable with a piezo polymer as the “dielectric” between a centre core and an outer braid. When the cable is compressed or stretched, a charge or voltage is generated proportional to the stress
Time for the reflection of light in an optical cable or a pulse in a cable, where a strain applied to a the cable causes reflections or absorptions of part of the signal
Capacitance change in a planar, coaxial or intertwined structure of a cable by changing the distance between or overlapping of capacitor plates

The method blocks illustrated in the flow charts may represent steps in a method and/or sections of code in the computer program 208a.

The illustration of a particular order to the method blocks of the flow charts does not necessarily imply that there is a required or preferred order for the blocks and the order and arrangement of the block may be varied. Furthermore, it may be possible for some steps to be omitted.

It will be understood that each block and combinations of blocks, can be implemented by various means, such as hardware, firmware, and/or software including one or more computer program instructions. For example, one or more of the procedures described above may be embodied by computer program instructions. In this regard, the computer program instructions which embody the procedures described above may be stored by a memory storage device and performed by a processor. As will be appreciated, any such computer program instructions may be loaded onto a computer or other programmable apparatus (i.e., hardware) to produce a machine, such that the instructions which performed on the programmable apparatus create means for implementing the functions specified in the blocks. These computer program instructions may also be stored in a computer-readable medium that can direct a programmable apparatus to function in a particular manner, such that the instructions stored in the computer-readable memory produce an article of manufacture including instruction means which implement the function specified in the blocks. The computer program instructions may also be loaded onto a programmable apparatus to cause a series of operational steps to be performed on the programmable apparatus to produce a computer-implemented process such that the instructions which are performed on the programmable apparatus provide steps for implementing the functions specified in the blocks.

In the description above, the wording ‘connect’, ‘couple’ and “communication” their derivatives mean operationally connected/coupled and in communication. It should be appreciated that any number or combination of intervening components can exist (including no intervening components).

References to ‘computer-readable storage medium’, ‘computer program product’, ‘tangibly embodied computer program’ etc. or a ‘controller’, ‘computer’, ‘processor’ etc. should be understood to encompass not only computers having different architectures such as single/multi-processor architectures and sequential (Von Neumann)/parallel architectures but also specialized circuits such as field-programmable gate arrays (FPGA), application specific circuits (ASIC), signal processing devices and other devices. References to computer program, instructions, code etc. should be understood to encompass software for a programmable processor or firmware such as, for example, the programmable content of a hardware device whether instructions for a processor, or configuration settings for a fixed-function device, gate array or programmable logic device etc.

Embodiments of the present invention provide both a method and corresponding apparatus consisting of various modules or means that provide the functionality for performing the method. The modules or means may be implemented as hardware, or may be implemented as software or firmware to be performed by a computer processor. In particular, in the case of firmware or software, embodiments of the invention can be provided as a computer program product including a computer readable storage structure embodying computer program code (i.e. the software or firmware) thereon for performing by the computer processor.

The apparatus may be provided in a module. As used here ‘module’ refers to a unit or apparatus that excludes certain parts/components that would be added by an end manufacturer or a user.

Features described in the preceding description may be used in combinations other than the combinations explicitly described.

Although functions have been described with reference to certain features, those functions may be performable by other features whether described or not.

Although features have been described with reference to certain embodiments, those features may also be present in other embodiments whether described or not.

Although various embodiments of the present invention have been described in the preceding paragraphs with reference to various examples, it should be appreciated that modifications to the examples given can be made without departing from the scope of the invention as claimed.

Whilst endeavouring in the foregoing specification to draw attention to those features of the invention believed to be of particular importance it should be understood that the Applicant claims protection in respect of any patentable feature or combination of features hereinbefore referred to and/or shown in the drawings whether or not particular emphasis has been placed thereon.

1. A method comprising causing, at least in part, actions that result in:
receiving a signal relating to a detection of a touch on a cable;
determining a location on the cable of the touch; and
controlling an apparatus, which is in communication with the cable, based on the detected touch and the determined location of the touch.

2. The method as claimed claim 1, further comprising causing, at least in part, actions that result in determining at least one of:
a magnitude of the touch;
a direction of the touch; and
a time of the detection of the touch.

3. The method as claimed in claim 2, wherein controlling the apparatus is based on at least one of the: magnitude, direction and time of the touch.

4. The method as claimed in claim 1, further comprising causing, at least in part, actions that result in receiving a signal relating to a detection of a bend in the cable; and wherein controlling the apparatus is based on the detected bend.

5. The method as claimed in claim 4, further comprising causing, at least in part, actions that result in determining at least one of:
a magnitude of the bend;
a direction of the bend;
a location of the bend; and
a time of the detection of the bend.

6. The method as claimed in claim 5, wherein controlling the apparatus is based on at least one of the: magnitude, direction, location and time of the bend.

7. The method as claimed in claim 1, further comprising causing, at least in part, actions that result in receiving a signal relating to a detection of a stretch or contraction of the cable; and wherein controlling the apparatus is based on the detected stretch or contraction.

8. The method as claimed in claim 7, further comprising causing, at least in part, actions that result in determining at least one of:
a magnitude of the stretch or contraction;
a direction of the stretch or contraction; and
a location of the stretch or contraction; and
a time of the detection of the stretch or contraction.

9. The method as claimed in claim 8, wherein controlling the apparatus is based on at least one of the: magnitude, direction, location and time of the stretch or contraction.

10. The method as claimed in claim 1, comprising causing at least in part actions that result in receiving a plurality of signals related to at least one of:
a plurality of touches of the cable;
a plurality of locations of the plurality of touches;
a plurality of bends of the cable;
a plurality of stretches of the cable; and
a plurality of contractions of the cable.

11. The method as claimed in claim 10, wherein controlling the apparatus is based on at least one of:
the plurality of touches of the cable;
the plurality of locations of the plurality of touches;
the plurality of bends of the cable;
the plurality of stretches of the cable; and
the plurality of contractions of the cable.

12. The method as claimed in claim 1, further comprising causing, at least in part, actions that result in determining a manipulation of the cable based at least one of:
at least one of: a magnitude, a direction, a location and a time of the touch of the cable;
at least one of: a magnitude, a direction, a location and a time of a bend of the cable;
at least one of: a magnitude, a direction, a location and a time of a stretch of the cable; and
at least one of: a magnitude, a direction, a location and a time of a contraction of the cable.

13. The method as claimed claim 12, wherein determining the manipulation comprises determining at least one of: a degree, a direction, a location and a timing of the manipulation.

14. The method as claimed in claim 13, wherein controlling the apparatus is based on the determined manipulation.

15. The method as claimed in claim 1, further comprising causing, at least in part, actions that result in providing user feedback to at least a portion of the cable responsive to the signal.

16. The method as claimed in claim 1, further comprising causing, at least in part, actions that, responsive to the signal, result in:
an audio output, a visual output or a haptic output.

17. An apparatus comprising:
at least one processor; and
at least one memory storing computer program instructions configured, working with the at least one processor, to cause the apparatus to perform the method as claimed in claim 1.

18. An apparatus comprising means for performing the method as claimed in claim 1.

19. A device or module comprising the apparatus of claim 17.

20. The device of claim 19 wherein the device is configured for at least one of: mobile telephony, wireless communication and hand portability.

21. A non-transitory computer readable medium storing computer program instructions that, when performed by at least one processor, cause the method as claimed in claim 1 to be performed.

22. A cable comprising at least one sensor configured to:
detect a touch of a cable; and
generate a signal for controlling an apparatus, which is in communication with the cable, wherein the signal is representative of the detected touch and a location of the touch.

23. The cable as claimed in claim 22, wherein the cable comprises at least one sensor configured to detect at least one of:
a bend in the cable;
a stretch of the cable; and
a contraction of the cable.

24. The cable as claimed in claim 23, wherein the cable comprises at least one sensor configured to determine at least one of:
a magnitude, a direction, a location and time of at least one of:
the bend in the cable;
the stretch of the cable; and
the contraction of the cable.

25. The cable as claimed in claim 22, wherein the at least one sensor is located in a sensing portion of the cable, and wherein:
a visual appearance of the sensing portion differs from a visual appearance of other portions of the cable;
a cross-sectional dimension of the sensing portion differs to a cross sectional area of other portions of the cable;
a texture of the sensing portion differs to a texture of other portions of the cable.

26. The cable as claimed in claim 22, wherein the sensor is embedded within the cable.

27. The cable as claimed in claim 22, wherein the cable is configured to convey signals from the apparatus to a device.

28. The cable as claimed in claim 22, wherein the cable comprises a user feedback device whose operation is responsive to the signal.

29. A system comprising:
the apparatus of claim 17 and a cable comprising at least one sensor configured to detect a touch of the cable and generate a signal for controlling the apparatus, which is in communication with the cable, wherein the signal is representative of the detected touch and a location of the touch.
